(19) United States
(12) Patent Application Publication
(10) Pub. No.: US 2025/0125245 A1
(43) Pub. Date: Apr. 17, 2025

(54) SEMICONDUCTOR PACKAGE AND WIRING SUBSTRATE USED FOR THE SAME

(71) Applicant: SAMSUNG ELECTRONICS CO., LTD., SUWON-SI, GYEONGGI-DO (KR)

(72) Inventor: Hansae Lim, Suwon-si (KR)

(21) Appl. No.: 18/628,890

(22) Filed: Apr. 8, 2024

(30) Foreign Application Priority Data
Oct. 13, 2023 (KR) 10-2023-0136894

(51) Int. Cl. H01L 23/498; H01L 23/00; H01L 23/31

(52) U.S. Cl. CPC H01L 23/49838; H01L 23/3107; H01L 23/49822; H01L 24/16; H01L 2224/16225

(57) ABSTRACT

A semiconductor package includes a wiring substrate including a wiring pattern, a solder resist layer disposed on the wiring pattern and including an opening region, and a first penetrating contact disposed in the opening region of the solder resist layer. The semiconductor chip disposed in the opening region and connected to the wiring substrate. The molding portion includes a first portion covering the semiconductor chip and a second portion disposed below the semiconductor chip. The second portion includes a penetrating molding portion disposed in the first penetrating contact.

### CROSS-REFERENCE TO RELATED APPLICATION

This application claims priority to and the benefit of Korean Patent Application No. 10-2023-0136894, filed in the Korean Intellectual Property Office on Oct. 13, 2023, the entire contents of which are herein incorporated by reference.

### BACKGROUND

### (a) Technical Field

The present disclosure relates to a semiconductor package and a wiring substrate used for the same, and more particularly, to a semiconductor package having an improved structure and a wiring substrate used for the same.

### (b) Discussion of Related Art

A semiconductor device may perform various functions. A semiconductor device may have a small size. Accordingly, semiconductor devices are widely used in various electronic industries. Advancements in the electronic industry have followed research on packaging technology, which proposed reductions in a size of the semiconductor devices while also increasing performance of the semiconductor devices.

### SUMMARY

The present disclosure attempts to provide to a semiconductor package capable of enhancing performance and an integration degree and a wiring substrate used for the same.

According to an embodiment, a semiconductor package according to an embodiment includes a wiring substrate including a wiring pattern, a solder resist layer disposed on the wiring pattern and including an opening region, and a first penetrating contact disposed in the opening region of the solder resist layer, a semiconductor chip disposed in the opening region and connected to the wiring substrate, and a molding portion including a first portion covering the semiconductor chip and a second portion disposed below the semiconductor chip, the second portion including a penetrating molding portion disposed in the first penetrating contact.

According to an embodiment, a semiconductor package according to an embodiment includes a wiring substrate including a vent penetrating contact in a first region and a penetrating contact in a second region, a semiconductor chip disposed on the wiring substrate, and a molding portion including a first portion covering the semiconductor chip on the wiring substrate and a second portion disposed below the semiconductor chip, the second portion of the molding portion including a penetrating molding portion disposed in the vent penetrating contact in the first region, wherein the penetrating contact in the second region includes a material different from the penetrating molding portion in the first region.

According to an embodiment, a wiring substrate for a semiconductor package according to an embodiment includes a base member, a wiring pattern disposed on the base member, a solder resist layer disposed on the wiring pattern and including an opening region, and a first penetrating contact disposed in the opening region and having an inner hole.

### BRIEF DESCRIPTION OF THE DRAWINGS

FIG. 1 is a plan view schematically illustrating a semiconductor package according to an embodiment.

FIG. 2 is a cross-sectional view taken along a line A-A′ of FIG. 1.

FIG. 3 is a rear plan view schematically illustrating a rear surface of the semiconductor package illustrated in FIG. 1.

FIG. 4 is a plan view illustrating a wiring substrate included in the semiconductor package illustrated in FIG. 1.

FIG. 5A and FIG. 5B are plan views schematically illustrating a first penetrating contact and a second penetrating contact included in the semiconductor package illustrated in FIG. 1, respectively.

FIG. 6, FIG. 7, FIG. 8, FIG. 9, and FIG. 10 illustrate a manufacturing method of a semiconductor package according to an embodiment.

### DETAILED DESCRIPTION

Embodiments of the present disclosure will be described more fully hereinafter with reference to the accompanying drawings for those skilled in the art to which the present disclosure pertains to easily practice the present disclosure. The present disclosure may be implemented in various different forms and is not limited to embodiments provided herein.

A portion unrelated to the description is omitted in order to clearly describe the present disclosure, and the same or similar components are denoted by the same reference numeral throughout the present specification.

Further, since sizes and thicknesses of portions, regions, members, units, layers, films, etc., shown in the accompanying drawings may be arbitrarily shown for better understanding and convenience of explanation, the present disclosure is not limited to the illustrated sizes and thicknesses. In the drawings, thicknesses of portions, regions, members, units, layers, films, etc., may be enlarged or exaggerated for convenience of explanation.

It will be understood that when a component such as a layer, film, region, or substrate is referred to as being “on” another component, it may be directly on other component or an intervening component may also be present. In contrast, when a component is referred to as being “directly on” another component, there is no intervening component present. Further, when a component is referred to as being “on” or “above” a reference component, a component may be positioned on or below the reference component, and does not be “on” or “above” the reference component toward an opposite direction of gravity.

In addition, unless explicitly described to the contrary, the word “comprise”, “include”, or “contain”, and variations such as “comprises”, “comprising”, “includes”, “including”, “contains” or “containing” will be understood to imply the inclusion of other components rather than the exclusion of any other components.

Further, throughout the specification, a phrase “on a plane”, “in a plane”, “on a plan view”, or “in a plan view” may indicate a case where a portion is viewed from above or a top portion, and a phrase “on a cross-section” or “in a cross-section” may indicate when a cross-section taken along a vertical direction is viewed from a side.

According to an embodiment, in a semiconductor package, a first penetrating contact may function as a vent hole and a penetrating contact in an opening region of a solder resist layer, and in a molding process, a flow rate of a molding material may be decreased and void formation may be prevented or reduced, and an integration degree of a wiring pattern may be enhanced and a size of the semiconductor package may be reduced. Accordingly, performance and reliability of the semiconductor package may be improved. Performance and reliability of the semiconductor package effectively realized in the semiconductor package with a flip chip structure and/or a molded underfill structure.

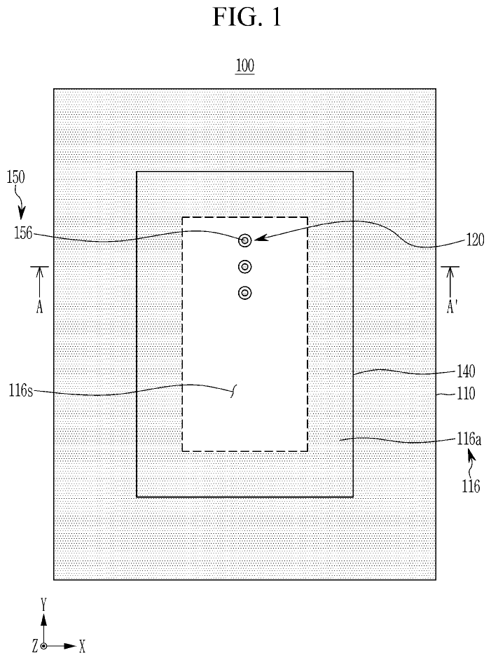

Hereinafter, a semiconductor package 100 according to an embodiment will be described in detail with reference FIG. 1 to FIG. 5B.

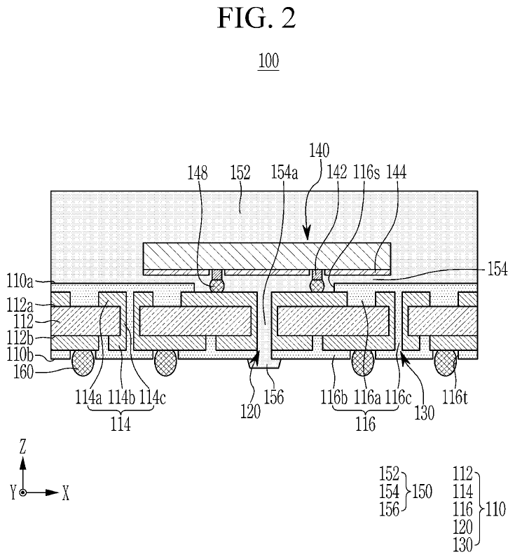

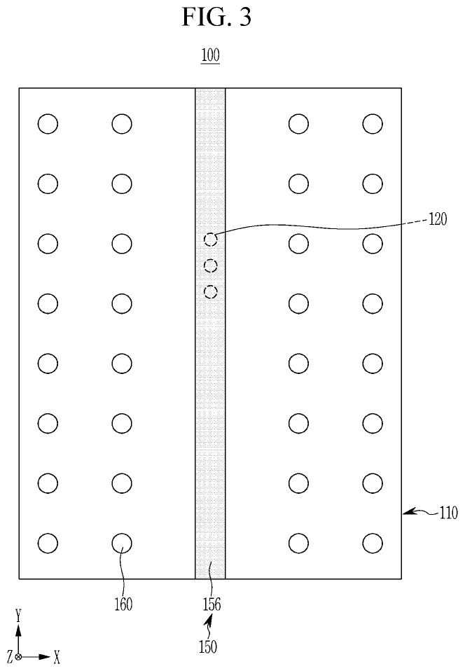

FIG. 1 is a plan view schematically illustrating a semiconductor package according to an embodiment. FIG. 2 is a cross-sectional view taken along a line A-A′ of FIG. 1. FIG. 3 is a rear plan view schematically illustrating a rear surface of the semiconductor package illustrated in FIG. 1.

For purposes of illustration and a clear understanding, a penetrating molding portion 154a of a molding portion 150 is illustrated in FIG. 1, while some other portions of the molding portion 150 may not be illustrated. A third portion 156 of the molding portion 150 and an outer interconnection member 160 are illustrated in FIG. 3, while a second resist portion 116b is not illustrated.

Referring to FIG. 1, FIG. 2, and FIG. 3, a semiconductor package 100 according to an embodiment may include a wiring substrate 110, a semiconductor chip 140, and a molding portion 150.

The wiring substrate 110 may include a base member 112, a wiring pattern 114, a solder resist layer 116, and a first penetrating contacts 120 and a second penetrating contact 130.

In an embodiment, the wiring substrate 110 may include a first surface 110a (e.g., an upper surface) and a second surface 110b (e.g., a lower surface) disposed opposite to the first surface 110a. The first surface 110a may be disposed facing the semiconductor chip 140. For example, the semiconductor chip 140 may be disposed on the first surface 110a of the wiring substrate 110, and an outer interconnection member 160 may be disposed on the second surface 110b of the wiring substrate 110.

An interconnection member 148 may be disposed at on the first surface 110a of the wiring substrate 110. The interconnection member 148 may be disposed between the first surface 110a of the wiring substrate 110 and the semiconductor chip 140. The wiring substrate 110 and the semiconductor chip 140 may be electrically connected to each other via the interconnection member 148. The semiconductor package 100 may be connected or interconnected to an external circuit, an external device, a mother board, or the like by the outer interconnection member 160 disposed on the second surface 110b. However, embodiments are not limited thereto and various modifications are possible.

The outer interconnection member 160 may have a land shape, a ball shape, a pin shape, or a bump shape. The outer interconnection member 160 may include at least one of tin, lead, bismuth, silver, copper, aluminum, tungsten, nickel, manganese, cobalt, titanium, tantalum, ruthenium, beryllium, indium, molybdenum, magnesium, rhenium, or gallium, or an alloy including the same. For example, the outer interconnection member 160 may include tin or an alloy including tin (e.g., a Sn—Ag alloy or a Sn—Ag—Cu alloy). However, embodiments are not limited thereto and a shape, a material, or the like of the outer interconnection member 160 may be variously modified.

The outer interconnection member 160 may perform various functions according to a design or an implementation. For example, the outer interconnection member 160 may be an outer interconnection member for a ground connection, an outer interconnection member for a power supply, an outer interconnection member for communicating a signal, or the like.

The base member 112 may structurally support the semiconductor chip 140. The base member 112 may include any of various insulating materials, for example, a resin. The base member 112 may be formed by using a prepreg material (e.g., resin impregnated glass fiber). A resin included in the base member 112 may include a thermosetting resin such as an epoxy resin, a phenolic resin, or the like, or a thermoplastic resin such as polyetherketone, polyimide, or the like. Embodiments are not limited to a material of the base member 112 and various modifications are possible.

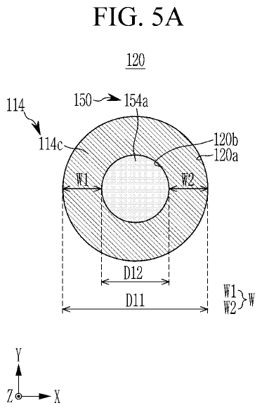

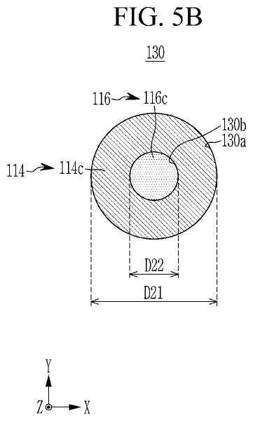

The base member 112 may include a first surface 112a (e.g., an upper surface) and a second surface 112b (e.g., a lower surface) disposed opposite to the first surface 112a. The wiring pattern 114 may be disposed on at least one of the first surface 112a and the second surface 112b of the base member 112. In an embodiment, the wiring pattern 114 may include a first wiring portion 114a disposed on the first surface 112a of the base member 112 and a second wiring portion 114b on the second surface 112b of the base member 112. The wiring pattern 114 may include an extension portion 114c disposed on an inner surface of a first penetrating hole 120a (refer to FIG. 5A) of the first penetrating contact 120 included in the base member 112. The extension portion 114c of the wiring pattern 114 may be disposed on an inner surface of a penetrating hole 130a (refer to FIG. 5B) of the second penetrating contact 130 included in the base member 112. The extension portion 114c may be disposed on the inner surface of the first penetrating hole 120a of the first penetrating contact 120 and/or the penetrating hole 130a of the second penetrating contact 130, and may connect the first wiring portion 114a and the second wiring portion 114b.

In this specification, the extension portion 114c in the first penetrating contact 120 and/or the second penetrating contact 130 is described as a part of the wiring pattern 114. In some embodiments, the extension portion 114c may be considered as a part of the first penetrating contact 120 and/or the second penetrating contact 130.

In an example land structure of the interconnection member 148 of the semiconductor chip 140, a portion of the first wiring portion 114a may be exposed by an opening region 116s of a first resist portion 116a. In an example land structure of the outer interconnection member 160, the outer interconnection member 160 may be disposed at a portion of the second wiring portion 114b exposed by an opening 116t of a second resist portion 116b. The land structure may have a pad shape. A pad shape may enhance a connection property of the interconnection member 148 or the outer interconnection member 160. The land structure may include a layer formed of a material disposed on the interconnection member 148 or the outer interconnection member 160, and the material may for improve the connection property. However, embodiments are not limited thereto. In some embodiments, the land structure may have the same shape or material as other portions of the interconnection member 148 or the outer interconnection member 160, for example.

The wiring pattern 114 may perform various functions according to a design or implementation. For example, the wiring pattern 114 may include a ground pattern, a power pattern, and a signal pattern. The signal pattern may be, or include a pattern for transmitting a signal. The signal pattern may be, or include a pattern for transmitting data signals or the like. A signal applied to the ground pattern, the power pattern, or the like may not include a data signal. The first penetrating contact 120 and/or the second penetrating contact 130 may include a penetrating contact for ground, a penetrating contact for power, a penetrating contact for signal, or the like.

The wiring pattern 114 (more particularly, the first wiring portion 114a, the second wiring portion 114b, or the extension portion 114c) may include a plating layer formed by a plating. However, embodiments are not limited thereto and the wiring pattern 114 may be formed by using various processes.

The wiring pattern 114 (more particularly, the first wiring portion 114a, the second wiring portion 114b, or the extension portion 114c) may include at least one of copper, aluminum, tungsten, nickel, gold, tin, manganese, cobalt, titanium, tantalum, ruthenium, and beryllium, or an alloy including the same. However, embodiments are not limited thereto and a material of the wiring pattern 114 may be variously modified.

In an embodiment, the first wiring portion 114a, the second wiring portion 114b, and the extension portion 114c of the wiring pattern 114 may include or be formed of the same layer including the same material and being continuously connected. However, embodiments are not limited thereto. In some embodiments, at least one of the first wiring portion 114a, the second wiring portion 114b, and the extension portion 114c of the wiring pattern 114 may include a material different from other portion of the first wiring portion 114a, the second wiring portion 114b, and the extension portion 114c of the wiring pattern 114.

In an example, the wiring pattern 114 may have a two-layered structure including the first wiring portion 114a and the second wiring portion 114b. However, embodiments are not limited thereto. In some embodiments, the wiring pattern 114 may have a single-layered structure including a wiring portion on one of the first surface 112a and the second surface 112b of the base member 112. In some embodiments, an additional one or more base member may be disposed on the base member 112, and the wiring pattern 114 may further include an additional one or more wiring portion on the additional one or more base member. For example, the wiring pattern 114 may include wiring portions of three or more layers (e.g., four layers to six layers). In an example, the extension portion 114c of the wiring pattern 114 may connect at least two wiring portions among the wiring portions of three or more layers in the first penetrating contact 120 and/or the second penetrating contact 130.

The solder resist layer 116 may include a first resist portion 116a and a second resist portion 116b. The first resist portion 116a may be disposed on the first surface 112a of the base member 112 or the first wiring portion 114a. The second resist portion 116b may be disposed on the second surface 112b of the base member 112 or the second wiring portion 114b. The solder resist layer 116 may include a penetrating resist portion 116c filling the second penetrating contact 130. The solder resist layer 116 may be formed by coating an ink material or a film, but embodiments are not limited thereto.

The solder resist layer 116 (more particularly, the first resist portion 116a) may have an opening region 116s at a region where the interconnection member 148 of the semiconductor chip 140 is positioned. The opening region 116s may be referred to as a first region. A region where the first resist portion 116a is positioned, other than the opening region 116s, may be referred to as a cover region or a second region.

The opening region 116s may expose a part of the first wiring portion 114a of the wiring substrate 110. The interconnection member 148 of the semiconductor chip 140 may be connected to the first wiring portion 114a of the wiring substrate 110. The opening region 116s may be disposed at a central portion of the wiring substrate 110, and the semiconductor chip 140 may be disposed at the central portion of the wiring substrate 110. The semiconductor chip 140 may be electrically connected to the first wiring portion 114a of the wiring substrate 110 in the opening region 116s. In an embodiment, the semiconductor chip 140 may be mounted on the wiring substrate 110 in the opening region 116s, and may electrically connected to pads outside of the opening region 116s, for example, by bonding wires. In an example, the semiconductor chip 140 may include a plurality of chips with one or more electrical connections to the wiring pattern 114 of the wiring substrate 110.

In a plan view, an area of the opening region 116s may be smaller than an area of the semiconductor chip 140. Accordingly, the first wiring portion 114a may be stably protected by the first resist portion 116a. However, embodiments are not limited thereto and a position, an area, or the like of the opening region 116s may be variously modified.

The second resist portion 116b may include the opening 116t corresponding to the outer interconnection member 160. For example, the opening 116t of the second resist portion 116b may one-to-one correspond to the outer interconnection member 160 and thus the second resist portion 116b may stably protect the second wiring portion 114b. However, embodiments are not limited thereto and a shape, an arrangement, or the like of the opening 116t may be variously modified.

In an embodiment, the penetrating contacts 120 and 130 in the wiring substrate 110 may include a first penetrating contact 120 in the opening region 116s of the solder resist layer 116 and a second penetrating contact 130 in the cover region. The first wiring portion 114a and the second wiring portion 114b may be disposed at a periphery of the penetrating contact 120 and/or 130 on the first surface 112a and the second surface 112b of the base member 112, respectively. The extension portion 114c in the penetrating contact 120 and/or 130 may connect the first wiring portion 114a and the second wiring portion 114b. In an example, a material disposed at an inside of the first penetrating contact 120 may be different from a material disposed at an inside of the second penetrating contact 130. This is described herein in more detail.

For example, the wiring substrate 110 may include or be a printed circuit board (PCB). However, embodiments are not limited thereto. In some embodiments, the wiring substrate 110 may be include a redistribution portion, a redistribution substrate, an interposer, a connection substrate, or the like.

In an embodiment, the semiconductor chip 140 may include or be a memory chip for storing data, a non-memory chip for calculating, processing, or controlling information, a merged semiconductor chip merging a memory portion and a non-memory portion, or may include a plurality of chips. For example, the memory chip may be a volatile memory such as a dynamic random access memory (DRAM), a static random access memory (SRAM), or the like, or a non-volatile memory such as a NAND flash memory system. For example, the non-memory chip or the merged semiconductor chip may be a central processing unit (CPU), a graphic processing unit (GPU), a neural processing unit (NPU), a micro controller unit (MCU), an application processor (AP), an application-specific integrated circuit (ASIC), an image sensor, or the like. Accordingly, embodiments are not limited to a type, a kind, or the like of the semiconductor chip 140.

A semiconductor device portion including various circuit elements may be disposed on a surface of the semiconductor chip 140. The circuit elements may include an active element, such as a transistor or the like, or a passive element, such as a capacitor, a resistor, an inductor, or the like. The semiconductor device portion may further include a conductive wiring or a conductive plug configured to electrically connect the circuit elements, and an insulation layer configured to insulate the conductive wiring, the conductive plug, and/or the circuit elements that should not be electrically connected.

A pad 142 electrically connected to the semiconductor device portion and an insulation layer 144 may be disposed on a surface of the semiconductor chip 140. The surface of the semiconductor chip 140, or the pad 142 and the insulation layer 144 may face the first surface 110a of the wiring substrate 110. The pad 142 may include a pad portion, or may have a structure including a pad portion and a under bump metal (UBM) on the pad portion. The insulation layer 144 may include any of various insulating materials.

The semiconductor chip 140 may have a flip chip structure where the semiconductor chip 140 may be connected or bonded to the wiring substrate 110 by using the interconnection member 148.

It is illustrated in FIG. 2 as an example that a thickness of the pad 142 in a thickness direction (a Z-axis direction) may be larger than a thickness of the insulation layer 144 in the thickness direction and the pad 142 protrudes from the insulation layer 144. It is illustrated in FIG. 2 as an example that an area of the pad 42 may be smaller than an area of an opening of the insulation layer 144 and the pad 142 may be spaced from the insulation layer 144, and the interconnection member 148 may be disposed at a protrusion portion of the pad 142 and may not be disposed on the insulation layer 144 or between the pad 142 and the insulation layer 144. However, embodiments are not limited thereto. In some embodiments, in the thickness direction (the Z-axis direction in FIG. 2), the thickness of the pad 142 may be the same as, or smaller than the thickness of the insulation layer 144. In some embodiments, an area of the pad 42 may be the same as, or larger than an area of the opening of the insulation layer 144. The pad 142 may be disposed in contact with a side surface or an outer surface of the insulation layer 144. In some embodiments, the interconnection member 148 may be disposed on the side surface, or the outer surface of the insulation layer 144, or disposed between the pad 142 and the insulation layer 144. Other various modifications are possible.

The pad 142 may include at least one of copper, aluminum, tungsten, nickel, gold, tin, manganese, cobalt, titanium, tantalum, ruthenium, or beryllium, or an alloy including the same. However, embodiments are not limited thereto and a material of the pad 142 may be variously modified.

The insulation layer 144 may include any of various compounds or resins. For example, the insulation layer 144 may include an insulating material of the compound, such as oxide, nitride, oxynitride, or the like. In some embodiments, the insulation layer 144 may include a thermosetting resin such as an epoxy resin, a thermoplastic resin such as polyimide, a resin including an inorganic filler and/or a glass fiber, or the like. The insulation layer 144 may include a photosensitive resin such as a photoimageable dielectric (PID) material, or photosensitive polyimide (PSPI), or the like. The insulation layer 144 may include a single layer or a plurality of layers. In a case that the insulation layer 144 include the plurality of layers, an interface between the plurality of layers may vary according to a process. That is, the insulation layer 144 may include any of various materials or any of various stacking structures.

The interconnection member 148 may have a land shape, a ball shape, a pin shape, or a bump shape. When the interconnection member 148 and the outer interconnection member 160 have bump shapes, the interconnection member 148 may be a micro bump or a fine bump smaller than the outer interconnection member 160, but embodiments are not limited thereto. The interconnection member 148 may include at least one of tin, lead, bismuth, silver, copper, aluminum, tungsten, nickel, manganese, cobalt, titanium, tantalum, ruthenium, beryllium, indium, molybdenum, magnesium, rhenium, or gallium, or an alloy including the same. For example, the interconnection member 148 may include tin or an alloy including tin (e.g., a Sn—Ag alloy or a Sn—Ag—Cu alloy). However, embodiments are not limited thereto and a shape, a material, or the like of the interconnection member 148 may be variously modified.

In an embodiment, the wiring substrate 110 may have a first length in a first direction (an X-axis direction in FIG. 2), a second length larger than the first length in a second direction (a Y-axis direction in FIG. 2) that is transverse to the first direction, and a predetermined thickness in the thickness direction (the Z-axis direction in FIG. 2). The semiconductor chip 140 may have a size or an area smaller than a size or an area of the wiring substrate 110. For example, the size of the semiconductor chip 140 may be defined by a third length in the first direction, a fourth length in the second direction larger than the third length, and a predetermined thickness in the thickness direction (the Z-axis direction). The opening region 116s of the solder resist layer 116 may have a size or an area smaller than the size or the area of the semiconductor chip 140. For example, the size or area of the opening region 116s may be defined by a fifth length in the first direction, and a sixth length in the second direction larger than the fifth length. An edge of the semiconductor chip 140 may be spaced apart from an edge of the wiring substrate 110 at a predetermined distance. An edge of the opening region 116s may be spaced apart from the edge of the semiconductor chip 140 at a predetermined distance. Thereby, structural stability may be improved.

However, embodiments are not limited thereto. In some embodiments, the wiring substrate 110 may have the same length in the first direction and in the second direction, the semiconductor chip 140 may have the same length in the first direction and in the second direction, or the opening region 116s may have the same length in the first direction and in the second direction. In some embodiments, a distance between an edge of the wiring substrate 110 and an edge of the semiconductor chip 140 at a first portion may be different from a distance between an edge of the wiring substrate 110 and an edge of the semiconductor chip 140 at a second portion. In some embodiments, a distance between an edge of the semiconductor chip 140 and an edge of the opening region 116s at a first portion may be different from a distance between an edge of the semiconductor chip 140 and an edge of the opening region 116s at a second portion. In some embodiments, at least two of a long axis direction of the wiring substrate 110, a long axis direction of the semiconductor chip 140, and a long axis direction of the opening region 116s may be different. Other various modifications are possible.

The molding portion 150 may form a molding of the semiconductor chip 140. For example, the molding portion 150 may cover and/or surround the semiconductor chip 140 and/or the frame portion 20. According to an embodiment, the molding portion 150 may include one layer or a plurality of layers. The molding portion 150 may include a molding material, for example, a thermosetting resin such as an epoxy resin, a thermoplastic resin such as polyimide, a resin including an inorganic filler and/or a glass fiber, an epoxy molding compound (EMC), or the like. A material, a shape, or the like of the molding portion 150 may be variously modified.

In an embodiment, the molding portion 150 may include a first portion 152 and a second portion 154. The first portion 152 may cover the semiconductor chip 140 on the first surface 110a of the wiring substrate 110. The second portion 154 may be disposed at a lower portion of the semiconductor chip 140 and may include a penetrating molding portion 154a in the first penetrating contact 120. The molding portion 150 may further include a third portion 156 disposed on the second surface 110b of the wiring substrate 110.

In an example, the first portion 152 and the second portion 154, and/or the third portion 156 may have an integral structure including the same material and may be continuously connected. For example, the molding portion 150 may have a molded underfill (MUF) structure formed by a molded underfill (MUF) process. Here, in a molded underfill process, an additional process of filling a space between the wiring substrate 110 and the semiconductor chip 140 with a separate molding material may be omitted, and the space between the wiring substrate 110 and the semiconductor chip 140 may be filled together in a molding process of forming the molding portion 150 covering the semiconductor chip 140.

However, embodiments are not limited thereto. In some embodiments, at least one of the first portion 152, the second portion 154, and the third portion 156 of the molding portion 150 may include a different material, and may be separately formed. In some embodiments, the molding portion 150 may be formed by various processes other than a molded underfill process. In some embodiments, the molding portion 150 might not include the third portion 156.

In a plan view, the first portion 152 of the molding portion 150 may have the same size or area as the wiring substrate 110 and may entirely cover the semiconductor chip 140. In a plan view, the second portion 154 of the molding portion 150 may fill an entire portion of a space between the wiring substrate 110 and the semiconductor chip 140 and fill an inside of the first penetrating contact 120. In a plan view, the third portion 156 of the molding portion 150 may have a shape longitudinally extending in one direction (e.g., the Y-axis direction in FIG. 3) with a small width (e.g., in the X-axis direction).

In a cross-sectional view, in the thickness direction (the Z-axis direction in FIG. 2), a thickness of the molding portion 150 on the semiconductor chip 140 may be larger than a thickness of the molding portion 150 between the semiconductor chip 140 and the wiring substrate 110. In the thickness direction, a thickness of the third portion 156 of the molding portion 150 may be smaller than the thickness of the molding portion 150 on the semiconductor chip 140 or the thickness of the molding portion 150 between the semiconductor chip 140 and the wiring substrate 110. In the thickness direction, the thickness of the third portion 156 of the molding portion 150 may be smaller than a thickness of the outer interconnection member 160. In an embodiment, the third portion 156 of the molding portion 150 having a thickness smaller than the thickness of the outer interconnection member 160 may not interfere with a connection between the outer connection member 160 and the external device, the external circuit, the mother board, or the like.

However, embodiments are not limited thereto. In some embodiment, in a cross-sectional view, in the thickness direction (the Z-axis direction in FIG. 2), the thickness of the molding portion 150 on the semiconductor chip 140 may be the same as, or smaller than the thickness of the molding portion 150 between the semiconductor chip 140 and the wiring substrate 110. In some embodiment, in the thickness direction, the thickness of the third portion 156 of the molding portion 150 may be the same as, or larger than the thickness of the molding portion 150 on the semiconductor chip 140 or the thickness of the molding portion 150 between the semiconductor chip 140 and the wiring substrate 110.

In an embodiment, the penetrating molding portion 154a and the third portion 156 may be formed by a flow of a molding material in a molding process through a first inner hole 120b (refer to FIG. 5A) of the first penetrating contact 120 and a discharge path 219 (refer to FIG. 8). Accordingly, the first penetrating contact 120 and/or the penetrating molding portion 154a may be connected to the third portion 156.

As described herein, the first inner hole 120b of the first penetrating contact 120 may function as a vent hole in a molding process for forming the molding portion 150. That is, the first penetrating contact 120 may be a vent penetrating contact functioning as a vent hole and a penetrating contact. Accordingly, the first penetrating contact 120 may be different from the second penetrating contact 130, which may function as a penetrating contact in the cover region while not acting as a vent hole.

In an embodiment, in the opening region 116s of the solder resist layer 116, the first penetrating contact 120 may include one first penetrating contact 120 or a plurality of first penetrating contacts 120. Similarly, the penetrating molding portion 154a may include one penetrating molding portion 154a or a plurality of penetrating molding portions 154a. When the first penetrating contact 120 includes the plurality of first penetrating contacts 120 or the penetrating molding portion 154a includes the plurality of penetrating molding portions 154a in the opening region 116s of the solder resist layer 116, the molding material may smoothly flow in a molding process.

In an example, the plurality of first penetrating contacts 120 or the plurality of penetrating molding portions 154a may be spaced apart from each other in the second direction at regular intervals. More particularly, the third portion 156 may have a shape longitudinally extending in the second direction, the plurality of first penetrating contacts 120 or the plurality of penetrating molding portions 154a may be sequentially disposed in the second direction at regular intervals on the third portion 156. In an example in which the third portion 156 has a shape longitudinally extending in the second direction, and the plurality of first penetrating contacts 120 or the plurality of penetrating molding portions 154a are sequentially disposed in the second direction at regular intervals on the third portion 156, the molding material may smoothly flow in a molding process.

For example, the first penetrating contact 120 or the penetrating molding portion 154a may be disposed at a side of the opening region 116s of the solder resist layer 116 (e.g., at an upper side in FIG. 2). For example, when the opening region 116s is divided into a first side (e.g., the upper side) and a second side (e.g., a lower side) based on a center portion of the opening region 116s in the third direction, the first penetrating contact 120 or the penetrating molding portion 154a may be disposed at the first side, and may not be disposed at the second side. In a molding process, the first penetrating contact 120 may be disposed at a rear portion in a direction where the molding material flows. In an example in which the first penetrating contact 120 is disposed at the rear portion in a direction where the molding material flows, the molding material may be stably filled at a front portion and the molding material may flow stably at the rear portion.

It is illustrated in the drawing as an example that the third portion 156 may have a relatively small width in the first direction (the X-axis direction), which may be a short axis direction, and longitudinally extends in the second direction (the Y-axis direction), which may be a long axis direction, and the plurality of first penetrating contacts 120 or the plurality of penetrating molding portions 154a may be sequentially disposed in the second direction, which is the long axis direction. However, embodiments are not limited thereto. In a molding process, an arrangement of the third portion 156, the first penetrating contact 120, or the penetrating molding portion 154a may be variously modified depending on a discharge path of the molding material. In some embodiments, the third portion 156 may have a relatively small width in the second direction (the Y-axis direction), which is the long axis direction, and may longitudinally extend in the first direction (the X-axis direction), which is the short axis direction, and the plurality of first penetrating contacts 120 or the plurality of penetrating molding portions 154a may be sequentially disposed in the first direction, which is the short axis direction.

In an example, the third portion 156 of the molding portion 150 may longitudinally extend from a first edge of the wiring substrate 110 to a second edge of the wiring substrate 110 in an extension direction. However, embodiments are not limited thereto. In some embodiments, the third portion 156 of the molding portion 150 may be connected to the first penetrating contact 120 or the penetrating molding portion 154a at a portion where the first penetrating contact 120 or the penetrating molding portion 154a is positioned on the second surface 110b of the wiring substrate 110. Other various modifications are possible.

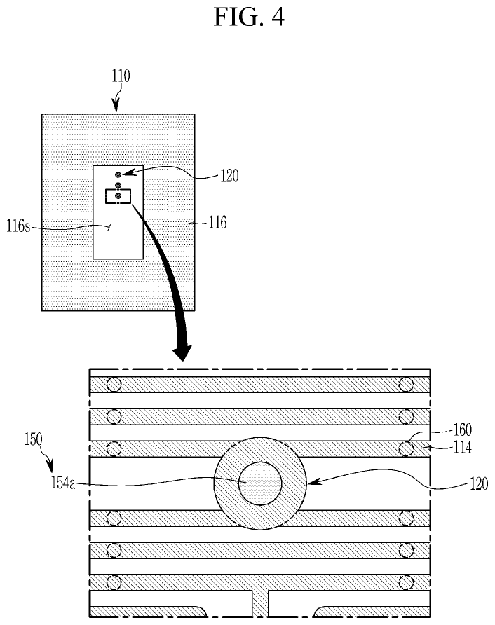

Referring to FIG. 4, FIG. 5A, and FIG. 5B, together with FIG. 1 to FIG. 3, the first penetrating contact 120 and the second penetrating contact 130 are described in more detail.

FIG. 4 is a plan view illustrating the wiring substrate 110 included in the semiconductor package 100 illustrated in FIG. 1. FIG. 5A and FIG. 5B are plan views schematically illustrating the first penetrating contact 120 and the second penetrating contact 130 included in the semiconductor package 100 illustrated in FIG. 1, respectively. For illustration and a clear understanding, the first penetrating contact 120 and the penetrating molding portion 154a therein are mainly illustrated in FIG. 5A, and the second penetrating contact 130 and the penetrating resist portion 116c therein are mainly illustrated in FIG. 5B.

Referring to FIG. 1 to FIG. 5B, in an embodiment, a material at an inside of the first penetrating contact 120 may be different from a material at an inside of the second penetrating contact 130.

The extension portion 114c of the wiring pattern 114 may be disposed on an inner surface of a first penetrating hole 120a of the first penetrating contact 120, and the penetrating molding portion 154a may be disposed in a first inner hole 120b of the first penetrating contact 120. For example, the penetrating molding portion 154a may fill an entire portion of the first inner hole 120b of the first penetrating contact 120. Here, the first penetrating hole 120a may refer to a hole penetrating the wiring substrate 110, and the first inner hole 120b may refer to a hole at an inside of the extension portion 114c of the wiring pattern 114 in the first penetrating contact 120.

In an embodiment, the molding portion 150 may be disposed in contact with at least a partial portion of the wiring pattern 114 in the first penetrating contact 120. For example, the second portion 154 of the molding portion 150 (e.g., an outer surface of the penetrating molding portion 154a) may be disposed in contact with an inner surface of the extension portion 114c of the wiring pattern 114, and the third portion 156 of the molding portion 150 may be disposed in contact with a rear surface of the extension portion 114c of the wiring pattern 114.

The extension portion 114c of the wiring pattern 114 may be disposed on an inner surface of a second penetrating hole 130a of the second penetrating contact 130. The penetrating resist portion 116c may be disposed in a second inner hole 130b of the second penetrating contact 130. For example, the penetrating resist portion 116c may fill an entire portion of the second inner hole 130b of the second penetrating contact 130. For example, the second penetrating contact 130 may be formed by a tenting process. Here, the second penetrating hole 130a may refer to a hole penetrating the wiring substrate 110, and the second inner hole 130b may refer to a hole disposed at an inside of the extension portion 114c of the wiring pattern 114 in the second penetrating contact 130.

However, embodiments are not limited thereto. In some embodiments, the second penetrating hole 130a of the second penetrating contact 130 may be entirely filled with the extension portion 114c of the wiring pattern 114, and the second inner hole 130b may be omitted. For example, the second penetrating contact 130 may be formed by a semi additive process (SAP). Other various modifications are possible. In an embodiment, a number of the first penetrating contact 120 in the opening region 116s may be smaller than a number of the second penetrating contact 130 in the cover region. The number of the first penetrating contact 120 may be sufficient to allow the molding material to flow stably in a molding process without blocking an electrical connection of the wiring pattern 114. For example, the molding material to flow stably in a molding process, while an electrical connection of the wiring pattern 114 may be clear of the molding material at the solder resist layer 116. The second penetrating contact 130 may have a relatively large number, and may connect the first wiring portion 114a and the second wiring portion 114b to deliver a ground voltage, a power voltage, one or more signals, or the like.

One or more of the first penetrating contacts 120 and/or one or more of the penetrating molding portions 154a may be disposed in the opening region 116s. For example, the number of the first penetrating contacts 120 and/or the number of the penetrating molding portions 154a may be two to six in the opening region 116s. When the number of the first penetrating contacts 120 and/or the number of the penetrating molding portions 154a is large, the molding material may be discharged more than a certain level through the first penetrating contacts 120 in a molding process and the molding portion 150 may be difficult to form stably. For example, the number of the first penetrating contacts 120 and/or the number of the penetrating molding portions 154a may be designed or implemented such that a volume of the molding material through the first penetrating contacts 120 and/or a flow rate of the molding material through the first penetrating contacts 120 may be less than a certain level, and the molding portion 150 may be reliably formed. However, embodiments are not limited thereto. In some embodiments, the number of the first penetrating contact 120 and/or the number of the penetrating molding portion 154a may be one in the opening region 116s, or the number of the first penetrating contacts 120 and/or the number of the penetrating molding portions 154a may be larger than six in the opening region 116s.

In an embodiment, the first penetrating contact 120 may be electrically connected to the wiring pattern 114 in the opening region 116s of the solder resist layer 116.

For example, the first penetrating contact 120 may connect patterns of the wiring pattern 114 disposed at sides of the opening region 116s and applying the same voltage to the semiconductor chip 140. For example, the first penetrating contact 120 may be a penetrating contact for ground configured to connect ground patterns of the wiring pattern 114 disposed at sides of the opening region 116s and applying the same ground voltage to the semiconductor chip 140. In some embodiments, the first penetrating contact 120 may be a penetrating contact for power configured to connect power patterns of the wiring pattern 114 disposed at sides of the opening region 116s and applying the same power voltage to the semiconductor chip 140.

In an embodiment, an inductance of the wiring substrate 110 may be reduced, power integration (PI) may be improved by increasing a path for applying a ground voltage or a power voltage, and electric properties of the semiconductor package 100 may be improved. For example, the wiring pattern 114 may be designed without considering an arrangement of the vent hole, which may improve a degree of design freedom of the semiconductor package 100, while a size of the semiconductor package 100 may be reduced.

The first penetrating contact 120 may be disposed in a central region of the opening region 116s in a transverse direction that is transverse to the wiring substrate 110 extending in the first direction (e.g., the X-axis direction in the drawing). For example, a center portion of the first penetrating contact 120 may be within about 5 mm (e.g., within about 1 mm) of the center portion of the opening region 116s at sides of the center portion of the opening region 116s in the transverse direction. Accordingly, the wiring pattern 114 at sides of the central region (e.g., in the transverse direction) may be reliably connected by the first penetrating contact 120. However, embodiments are not limited thereto and a position or an arrangement of the first penetrating contact 120 may be variously modified.

For example, it is illustrated in FIG. 4 that the first penetrating contact 120 connects the wiring pattern 114 in the short axis direction or the first direction (the X-axis direction in the drawing). However, embodiments are not limited thereto. In some embodiments, the first penetrating contact 120 may connect the wiring pattern 114 extending in the short axis direction, the long axis direction, and/or a direction that is transverse to the first and second directions.

In an example, the first penetrating contact 120 may be the penetrating contact for ground or the penetrating contact for power. However, embodiments are not limited thereto and the first penetrating contact 120 may be a penetrating contact for signal. The second penetrating contact 130 may include a penetrating contact for ground, a penetrating contact for power, a penetrating contact for signal, or the like.

A size of the first penetrating hole 120a of the first penetrating contact 120 may be larger than a size of the second penetrating hole 130a of the second penetrating contact 130. For example, a width or a diameter D11 of the first penetrating hole 120a may be larger than a width or a diameter D21 of the second penetrating hole 130a. Here, the width of the first or second penetrating hole 120a or 130a may refer to a maximum width of the first or second penetrating hole 120a or 130a.

A size of the first inner hole 120b of the first penetrating contact 120 may be larger than a size of the second inner hole 130b of the second penetrating contact 130. For example, a width or a diameter D12 of the first inner hole 120b may be larger than a width or a diameter D22 of the second inner hole 130b. Here, the width of the first or second inner hole 120b or 130b may refer to a maximum width of the first or second inner hole 120b or 130b.

In some embodiments, a size of the penetrating molding portion 154a in the first penetrating contact 120 may be larger than a size of the penetrating resist portion 116c in the second penetrating contact 130. For example, a width or a diameter of the penetrating molding portion 154a may be larger than a width or a diameter of the penetrating resist portion 116c. Here, the width of the penetrating molding portion 154a may refer to a maximum width of the penetrating molding portion 154a, and the width of the penetrating resist portion 116c may refer to a maximum width of the penetrating resist portion 116c.

In an embodiment, the molding material may stably flow in a molding process through the first inner hole 120b of the first penetrating contact 120.

However, embodiments are not limited thereto. The size of the first penetrating hole 120a may be substantially the same as the size of the second penetrating hole 130a. When the first penetrating hole 120a and the second penetrating hole 130a have the same size, the same apparatus may be used in a process of forming the first and second penetrating holes 120a and 130a at the wiring substrate 110. In an example where the first penetrating hole 120a and the second penetrating hole 130a have the same size, a manufacturing cost may be reduced. In some embodiments, the size of the first penetrating hole 120a may be smaller than the size of the second penetrating hole 130a. In some embodiments, the size of the first inner hole 120b of the first penetrating contact 120 may be the same as, or smaller than the size of the second inner hole 130b of the second penetrating contact 130. In some embodiments, the size of the penetrating molding portion 154a in the first penetrating contact 120 may be the same as, or smaller than the size of the penetrating resist portion 116c in the second penetrating contact 130.

In a plan view, the width or the diameter of the penetrating molding portion 154a, or the width or the diameter D12 of the first inner hole 120b in the first penetrating contact 120, may be greater than a width W1 or W2 of each extension portion 114c of the first penetrating contact 120. Here, in a plan view, the width of each extension portion 114c of the first penetrating contact 120 may refer to a thickness of the extension portion 114c on an inner surface of the first penetrating contact 120 or a width of the extension portion 114c in a direction perpendicular to the inner surface of the first penetrating contact 120. The molding material may stably flow in a molding process by the first penetrating contact 120. However, embodiments are not limited thereto. In some embodiments, the width or the diameter of the penetrating molding portion 154a, or the width or the diameter D12 of the first inner hole 120b in the first penetrating contact 120 may be greater than an entire width (e.g., W1+W2) of an extension portion 114c of the wiring pattern disposed on an inner surface of the first penetrating contact 120. In some embodiments, in a plan view, the width or the diameter of the penetrating molding portion 154a or the width or the diameter D12 of the first inner hole 120b in the first penetrating contact 120 may be the same as, or smaller than the width W1 or W2 of each extension portion 114c of the first penetrating contact 120.

For example, in a plan view, the width or the diameter of the penetrating molding portion 154a, or the width or the diameter D12 of the first inner hole 120b in the first penetrating contact 120, may be larger than a total width W of the extension portion 114c or the extension portions 114c of the first penetrating contact 120. Here, in a plan view, the total width W of the extension portion 114c, or the extension portions 114c of the first penetrating contact 120, may refer to a sum (W1+W2) of the widths of portions included in the extension portion 114c at inner surfaces of the first penetrating contact 120 on a line passing through a center portion of the first penetrating contact 120. The molding material may stably flow in a molding process by the first penetrating contact 120. However, embodiments are not limited thereto. In some embodiments, in a plan view, the width or the diameter of the penetrating molding portion 154a, or the width or the diameter D12 of the first inner hole 120b in the first penetrating contact 120, may be the same as, or smaller than the total width W of the extension portion 114c or the extension portions 114c of the first penetrating contact 120.

In the first penetrating contact 120, the width or the diameter D12 of the first inner hole 120b may be about 50 μm to about 200 μm. The first penetrating contact 120 having the first inner hole 120b of the above range may effectively function as a vent hole in a molding process. However, embodiments are not limited thereto. In some embodiments, in the first penetrating contact 120, the width or the diameter D12 of the first inner hole 120b may be smaller than about 50 μm or larger than about 200 μm.

In a plan view, a width of the extension portion 114c in the first penetrating contact 120 may be substantially the same as a width of the extension portion 114c in the second penetrating contact 130. In the present disclosure, the phrase that two widths are substantially the same may include a case in which the two widths are the same and a case in which there is a difference between the two widths within a process error (e.g., a difference within about 10%). However, embodiments are not limited thereto. When a drilling process is performed to remove the penetrating resist portion 116c in the first penetrating contact 120, the width of the extension portion 114c in the first penetrating contact 120 may be adjusted in the drilling process. Accordingly, the width of the extension portion 114c in the first penetrating contact 120 may be different from the width of the extension portion 114c in the second penetrating contact 130. Other various modifications are possible.

It is illustrated in the drawing as an example that each of the first penetrating hole 120a and the first inner hole 120b of the first penetrating contact 120 may have a circular plane shape, and the extension portion 114c in the first penetrating contact 120 may have an annular ring shape when viewed in a plan view. However, the first penetrating hole 120a or the first inner hole 120b of the first penetrating contact 120 may have any of various shapes, such as a polygon shape, an oval shape, or the like, and shapes of the first penetrating hole 120a and the first inner hole 120b may be different from each other.

It is illustrated in the drawing as an example that each of the second penetrating hole 130a and the second inner hole 130b of the second penetrating contact 130 may have a circular plane shape, and the extension portion 114c in the second penetrating contact 130 may have an annular ring shape when viewed in a plan view. However, the second penetrating hole 130a or the second inner hole 130b of the second penetrating contact 130 may have any of various shapes, such as a polygon shape, an oval shape, or the like, and shapes of the second penetrating hole 130a and the second inner hole 130b may be different from each other. A shape of the second penetrating hole 130a or the second penetrating hole 130b of the second penetrating contact 130 may be different from a shape of the first penetrating hole 120a or the first inner hole 120b of the first penetrating contact 120.

As described herein, the first penetrating contact 120 may be disposed in the opening region 116s of the solder resist layer 116. That is, in an embodiment, the first penetrating contact 120 of the vent penetrating contact may be disposed in the opening region 116s of the solder resist layer 116.

In a molding process, a thickness of a lower space of the semiconductor chip 140 may be smaller than a thickness of an upper space of the semiconductor chip 140, and the interconnection member 148 at the lower portion of the semiconductor chip 140 may function as a kind of obstacle. As a result, in a molding process, a flow rate of the molding material may be lowered in the lower space of the semiconductor chip 140, and a void may be positioned in the lower portion of the semiconductor chip 140. The void may be a type of defect and may deteriorate performance and reliability of the semiconductor package 100. In an embodiment, the first penetrating contact 120 acting as a vent hole may be in the opening region 116s of the solder resist layer 116, and a decrease in the flow rate and the void formation in the lower space of the semiconductor chip 140 may be prevented or reduced, while performance and reliability of the semiconductor package 100 may be improved.

In an example, the wiring pattern 114 may be electrically connected to the first penetrating contact 120 functioning as a penetrating contact, and the wiring pattern 114 may be disposed at a periphery of the first penetrating contact 120, which may improve an integration degree of the wiring pattern 114 and reduce a size of the semiconductor package 100.

Accordingly, the performance and the integration degree of the semiconductor package 100 may be improved. The described effect(s) may be more effectively realized in the semiconductor package 100 with a flip chip structure and/or a molded underfill structure.

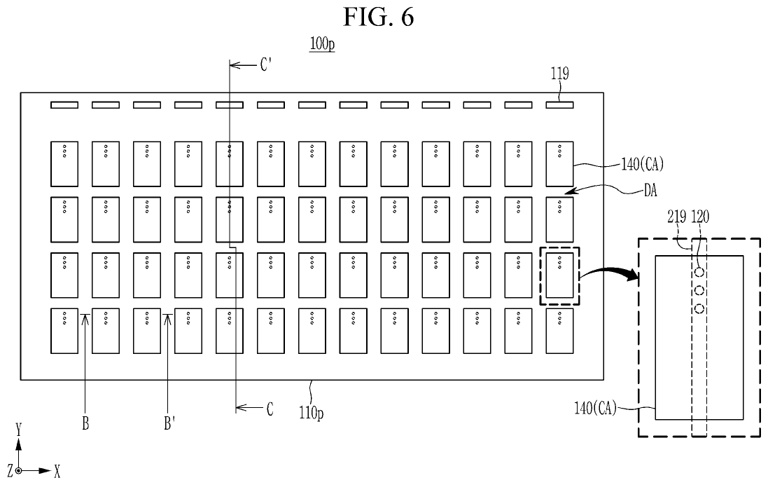

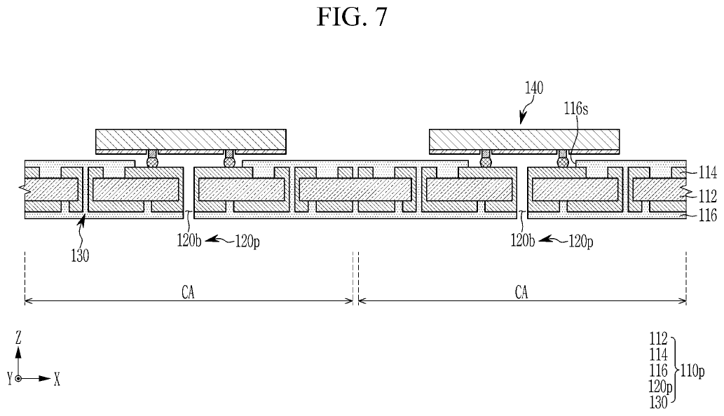

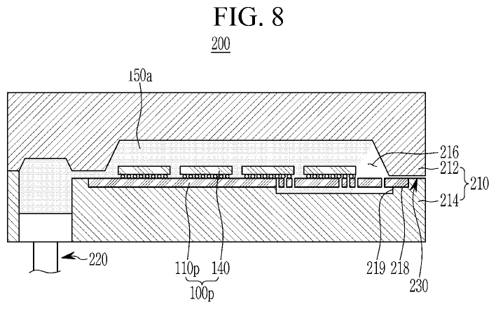

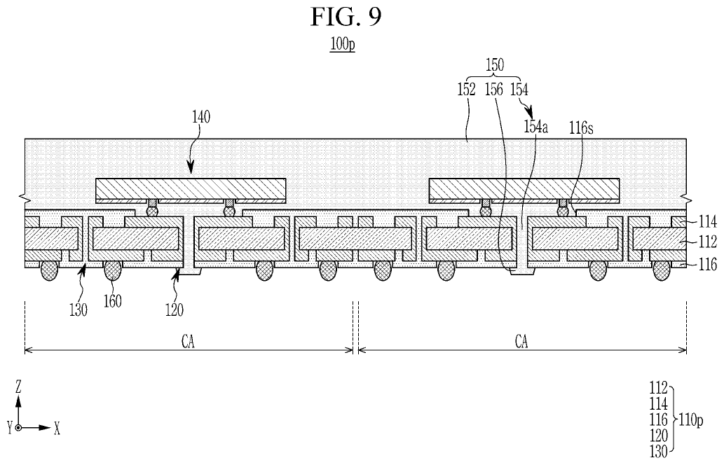

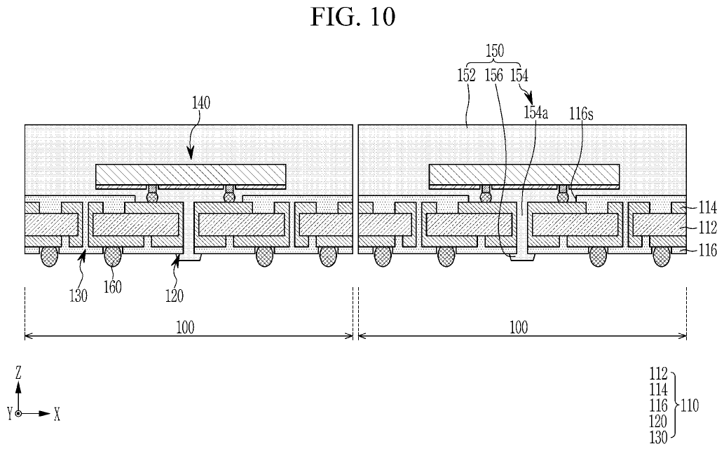

An embodiment of a manufacturing method for manufacturing a semiconductor package 100 will be described in detail with reference to FIG. 6 to FIG. 10. To the extent that an element is not described in detail in connection with FIG. 6 to FIG. 10, it may be understood that the element is at least similar to a corresponding element that has been described elsewhere within the present disclosure.

FIG. 6 to FIG. 10 illustrate a manufacturing method of a semiconductor package according to an embodiment.

FIG. 6 is a plan view illustrating a preliminary structure according to an embodiment before a molding process, and FIG. 7 is a cross-sectional view taken along a line of B-B′ in FIG. 6. Here, the preliminary structure 100p may refer to a structure before it is cut into a semiconductor package 100 of an individual type. For a clear understanding, a discharge path 219 included in a molding apparatus 200 illustrated in FIG. 8 is illustrated together in an enlarged view of FIG. 6.

Referring to FIG. 6 and FIG. 7, a preliminary structure 100p according to an embodiment may include a preliminary wiring substrate 110p and a plurality of semiconductor chips 140 on the preliminary wiring substrate 110p. The semiconductor chip 140 may be mounted in a chip region CA to have a flip chip structure by an interconnection member 148. Before a molding process, an outer interconnection member 160 (refer to FIG. 9) may not be provided. For example, an outer interconnection member 160 may be formed following a molding process.

The preliminary wiring substrate 110p may include chip regions CA in which the plurality of semiconductor chips 140 may be disposed and a cutting region DA. The cutting region DA may refer to a predetermined region where a portion to be scribed or cut when splitting the plurality of chip regions CA into an individual chip regions CA may be disposed. The cutting region DA may also be referred to as a scribe lane, a scribe line, an outer region, an external region, or the like. The cutting region DA may be disposed at an edge of the chip region CA to form a boundary of the chip region CA.

For example, a plurality of chip regions CA may be disposed in a first direction (an X-axis direction in the drawing) to form a single row, and a plurality of rows of chip regions CA may be disposed in a second direction (a Y-axis direction in the drawing) that is transverse to the first direction. The cutting region DA may include a plurality of first cutting regions extending in the first direction and a plurality of second cutting regions extending in the second direction. According to this, a structure of the cutting region DA may be simplified. However, embodiments are not limited thereto, and the first and/or second cutting region may have a bend portion, a bent portion, a rounded portion, or the like, depending on an arrangement of the plurality of chip regions CA.

A first preliminary penetrating contact 120p having a first inner hole 120b may be disposed in an opening region 116s of a solder resist layer 116 in the chip region CA of the preliminary wiring substrate 110p. After forming the solder resist layer 116, a drilling process may be performed to form a first inner hole 120b in the first preliminary penetrating contact 120p. In some embodiments, the solder resist layer 116 may be formed including a hole corresponding to the first inner hole 120b, and the first preliminary penetrating contact 120p may be formed in the first inner hole 120b.

A penetrating portion 119 may be disposed at an edge (an upper edge in FIG. 6) of the preliminary wiring substrate 110p in a second direction. A plurality of penetrating portions 119 may be disposed at regular intervals in a transverse direction (the X-axis direction in FIG. 6) that is transverse to the second direction. In the drawing, the penetrating portion 119 has been illustrated having a planar shape of a rectangular shape, but a planar shape of the penetrating portion 119 may have various shapes, such as a round shape, a polygonal shape other than a rectangular shape, an oval shape, or the like.

The first preliminary penetrating contact 120p may be disposed at a side adjacent to the edge (e.g., the upper edge in FIG. 6) of the preliminary wiring substrate 110p in the first direction in the opening region 116s of the solder resist layer 116. The edge may be a portion where a molding material is discharged in a molding process, and the other edge (e.g., a lower edge in FIG. 6) may be a portion where the molding material is injected. The penetrating portion 119 and the first preliminary penetrating contact 120p function as vent holes, and may prevent or reduce voids by allowing a smooth flow of a molding material in a molding process.

In an embodiment, a short axis direction of the semiconductor chip 140 may be parallel to a long axis direction of the preliminary wiring substrate 110p, and a long axis direction of the semiconductor chip 140 may be parallel to a short axis direction of the preliminary wiring substrate 110p. In a molding process, the molding material may be injected in the long axis direction of the semiconductor chip 140 or in the short axis direction of the preliminary wiring substrate 110p. However, embodiments are not limited thereto. The short or long axis direction of the semiconductor chip 140, the short or long axis direction of the preliminary wiring substrate 110p, the injected direction of the molding material, or the like may be variously modified.

FIG. 8 illustrates a molding process included in the manufacturing method of the semiconductor package according to an embodiment. FIG. 8 illustrates a cross-sectional view corresponding to a line of C-C′ in FIG. 6.

Referring to FIG. 8, in an embodiment, a molding apparatus 200 according to an embodiment may include a mold portion 210, a supply portion 220, and a discharge portion 230.

The mold portion 210 may include a plurality of molds. For example, the mold portion 210 may include a first mold 212 and a second mold 214, which may be combined together to form an inner space portion 216.

For example, at least one of the first mold 212 or the second mold 214 may be movable. The first mold 212 and/or the second mold 214 may have a detachable or openable structure and may include a structure (e.g., a clamping structure) stably holding the first mold 212 and/or the second mold 214. However, embodiments are not limited to a number of molds of the mold portion 210, the coupling structure, or the like.

In an example, the second mold 214 may have a recess portion or a mounting portion 218. The mounting portion 218 may have a size corresponding to the preliminary structure 100p (e.g., the preliminary wiring substrate 110p). In a molding process, the preliminary structure 100p (e.g., the preliminary wiring substrate 110p) may be mounted and fixed in the mounting portion 218. A discharge path 219 extending in a direction (e.g., a Y-axis direction of the drawings) may be disposed at a lower portion of the mounting portion 218. The discharge path 219 may be connected to the first preliminary penetrating contact 120p and may have a shape longitudinally extending in a first direction (e.g., the Y-axis direction). In an embodiment, in a second direction (e.g., the X-axis direction in the drawings) that is transverse to the first direction, the discharge path 219 may pass through a central portion of the semiconductor chip 140. However, embodiments are not limited thereto.

The inner space portion 216 may be a space where a molding process may be performed to the preliminary structure 100p. The inner space portion 216 may have a size, a shape, or the like corresponding to the preliminary structure 100p, and the size, the shape, or the like of the inner space portion 216 may be varied depending on a size, a shape, a type, or the like of the semiconductor chip 140.

In a first direction, the supply portion 220 may be disposed at a side or a front portion, and the discharge portion 230 may be disposed at an opposite side or a rear portion. A molding material 150a may be supplied through the supply portion 220 and air in the inner space portion 216 may be discharged through the discharge portion 230. The supply portion 220 may have any of various structures to supply the molding material 150a to the inner space portion 216, and the discharge portion 230 may have any of various structures through which the air may be discharged.

A molding process by the molding apparatus 200 may be described as follows. The preliminary structure 100p may be positioned at the molding apparatus 200 (e.g., the mounting portion 218). The molding material 150a may be supplied to the inner space portion 216 through the supply portion 220. In an example, the molding material 150a may flow through the first preliminary penetrating contact 120p of the preliminary wiring substrate 110p and the discharge path 219, and the molding material 150a may flow smoothly in a lower space of the semiconductor chip 140. A difference in flow rate of the molding material 150a at an upper space of the semiconductor chip 140 and at the lower space of the semiconductor chip 140 may be reduced, and void formation in the lower space of the semiconductor chip 140 may be prevented or reduced.

FIG. 9 is a plan view illustrating the preliminary structure in which a molding process and a process forming an outer interconnection member were performed. FIG. 9 illustrates a portion corresponding to the portion in FIG. 7.

Referring to FIG. 9, the preliminary structure 100p may include the preliminary wiring substrate 110p, the semiconductor chip 140, and the molding portion 150 formed by a molding process. In an example, the molding portion 150 may include a first portion 152 and a second portion 154. The first portion 152 may cover the semiconductor chip 140 on a first surface 110a of the preliminary wiring substrate 110p. The second portion 154 may be disposed at a lower portion of the semiconductor chip 140 and may include a penetrating molding portion 154a in the first penetrating contact 120. The molding portion 150 may further include a third portion 156 disposed on a second surface 110b of the preliminary wiring substrate 110p. The second portion 154 may be formed by the molding material 150a (refer to FIG. 8) flowing through the lower portion of the semiconductor chip 140 and the first penetrating contact 120. The third portion 156 may be formed by the molding material 150a flowing through the discharge path 219 at the lower portion of the preliminary wiring substrate 110p.

After a molding process, an opening may be formed on a second resist portion of the solder resist layer 116, which may be positioned on the second surface of a base member 112, and an outer interconnection member 160 may be formed.

FIG. 10 illustrates a cutting process included in the manufacturing method of the semiconductor package according to an embodiment.

Referring to FIG. 10, in a cutting process of the preliminary structure 100p (refer to FIG. 9), a plurality of the semiconductor package 100 may be formed by cutting the preliminary structure 100p along the cutting region between the plurality of chip regions CA. Various processes may be applied to perform a cutting process of the preliminary structure 100p.

According to an embodiment, the first penetrating contact 120 may be used as the vent hole in a molding process (e.g., a molded underfill process), a flow rate may be decreased, and void formation in the lower space of the semiconductor chip 140 may be prevented or reduced, which may improve performance and reliability of the semiconductor package 100. That is, the semiconductor package 100 with excellent performance and reliability may be formed in an efficient process by an improved structure.

While some examples have been described in connection with what is presently considered to be practical embodiments, it is to be understood that the disclosure is not limited, and that that the disclosure is intended to cover various modifications and equivalent arrangements included within the spirit and scope of the appended claims.

What is claimed is:

1. A semiconductor package, comprising:
a wiring substrate including a wiring pattern, a solder resist layer disposed on the wiring pattern and including an opening region, and a first penetrating contact disposed in the opening region of the solder resist layer;
a semiconductor chip disposed in the opening region and connected to the wiring substrate; and
a molding portion including a first portion covering the semiconductor chip and a second portion disposed below the semiconductor chip, the second portion including a penetrating molding portion disposed in the first penetrating contact.

2. The semiconductor package of claim 1, wherein the first portion and the second portion include a same material and have an integral structure.

3. The semiconductor package of claim 1, wherein the semiconductor chip connected to the wiring substrate by an interconnection member.

4. The semiconductor package of claim 1, wherein the first penetrating contact includes a plurality of first penetrating contacts, or
the penetrating molding portion includes a plurality of penetrating molding portions.

5. The semiconductor package of claim 4, wherein the plurality of first penetrating contacts are spaced apart in a second direction at regular intervals.

6. The semiconductor package of claim 1, wherein the first penetrating contact is disposed at a side of the opening region in a third direction.

7. The semiconductor package of claim 1, wherein the wiring substrate has a first surface facing the semiconductor chip and a second surface opposite to the first surface, and
the molding portion further includes a third portion disposed on the second surface of the wiring substrate.

8. The semiconductor package of claim 7, wherein the third portion of the molding portion has a shape longitudinally extending in a second direction, and
the first penetrating contact includes a plurality of first penetrating contacts disposed on the third portion.

9. The semiconductor package of claim 1, wherein the wiring substrate further includes a second penetrating contact disposed in a region where the solder resist layer is disposed, and
at least one of an extension portion of the wiring pattern or the solder resist layer disposed inside of the second penetrating contact.

10. The semiconductor package of claim 1, wherein the wiring substrate further includes a plurality of second penetrating contacts disposed in a region where the solder resist layer is disposed, and
a number of the first penetrating contact is smaller than a number of the plurality of second penetrating contacts.

11. The semiconductor package of claim 1, wherein the wiring substrate further includes a second penetrating contact disposed in a region where the solder resist layer is disposed, and
a size of the first penetrating contact is larger than a size of the second penetrating contact.

12. The semiconductor package of claim 1, wherein the wiring pattern is electrically connected to the first penetrating contact.

13. The semiconductor package of claim 12, wherein the first penetrating contact electrically connects portions of the wiring pattern disposed at different sides of the opening region and to which a same voltage is applied.

14. The semiconductor package of claim 1, wherein, in a plan view, a width of the penetrating molding portion is greater than a width of an extension portion of the wiring pattern on an inner surface of the first penetrating contact.

15. A semiconductor package, comprising:
a wiring substrate including a vent penetrating contact in a first region and a penetrating contact in a second region;
a semiconductor chip disposed on the wiring substrate; and
a molding portion including a first portion covering the semiconductor chip on the wiring substrate and a second portion disposed below the semiconductor chip, the second portion of the molding portion including a penetrating molding portion disposed in the vent penetrating contact in the first region,
wherein the penetrating contact in the second region includes a material different from the penetrating molding portion in the first region.

16. The semiconductor package of claim 15, wherein the wiring substrate comprises a wiring pattern and a solder resist layer disposed on the wiring pattern,
at least one of an extension portion of the wiring pattern and the solder resist layer is disposed inside of the penetrating contact, and
a size of the vent penetrating contact is larger than a size of the penetrating contact.

17. The semiconductor package of claim 15, wherein a number of the vent penetrating contact is smaller than a number of the penetrating contact.

18. A wiring substrate for a semiconductor package, comprising:
a base member;
a wiring pattern disposed on the base member;
a solder resist layer disposed on the wiring pattern and including an opening region; and
a first penetrating contact disposed in the opening region and having an inner hole.

19. The wiring substrate of claim 18, further comprising:
a second penetrating contact in a region covered by the solder resist layer,
wherein the opening region exposes the wiring pattern, and
wherein at least one of an extension portion of the wiring pattern and the solder resist layer is disposed inside of the second penetrating contact.

20. The wiring substrate of claim 18, wherein the wiring pattern is electrically connected to the first penetrating contact.
